(19) United States
(12) Patent Application Publication
(10) Pub. No.: US 2006/0221684 A1
(43) Pub. Date: Oct. 5, 2006

(54) Printing apparatus and control program updating method

(75) Inventor: Hisashi Iwai, Fukushima (JP)

Correspondence Address: AKIN GUMP STRAUSS HAUER & FELD L.L.P., ONE COMMERCE SQUARE, 2005 MARKET STREET, SUITE 2200, PHILADELPHIA, PA, 19103, US

(73) Assignee: Oki Data Corporation

(21) Appl. No.: 11/375,405

(22) Filed: Mar. 14, 2006

(30) Foreign Application Priority Data
Mar. 15, 2005 (JP) 2005-073547

(51) Int. Cl. G11C 16/04

(52) U.S. Cl. 365/185.03

(57) ABSTRACT

A printing apparatus which obtains, through a network, updating data for an updating process to update a control program for executing a printing process on the basis of print data has: a confirming unit which confirms its own operating state when the updating data is obtained; and an updating processing unit which starts the updating process in accordance with a confirmation result of the confirming unit. An evil associated with the updating of firmware can be prevented.

### BACKGROUND OF THE INVENTION

1. Field of the Invention

The invention relates to updating of a control program of a printing apparatus.

2. Related Background Art

A printing apparatus which executes a printing process on the basis of print data has a storing unit for holding a control program (firmware) to control the apparatus in order to execute the printing process. The firmware held in the storing unit is properly updated in order to improve a function of the printing process. The printing apparatus in which an updating process is executed on the basis of updating data which is obtained through a network has been disclosed in JP-A-2000-12345.

According to JP-A-2000-12345, there has been disclosed a technique in which the updating data obtained through the network is divided and transmitted and, when all of the divided updating data is collected, the firmware is updated.

Such a kind of printing apparatus in which the updating process of the firmware is executed by the network is arranged at a place away from a terminal of an updater which is connected to the network. Therefore, the updater cannot grasp an operating state of the printing apparatus. In such an arranging environment, the updating data is transmitted from the terminal of the updater to the printing apparatus and the printing apparatus updates the firmware on the basis of the obtained updating data.

The printing apparatus executes the updating process of the firmware on the basis of the updating data obtained through the network and, thereafter, reactivation called “reboot” is executed in the updating process.

Therefore, there is such a problem that, for example, if the updating process is executed during the printing process in which the non-processed print data exists, the non-processed print data is erased by the reboot. There is also such a problem that if the updating process is executed during the abnormal state such as jam (paper jam), opening of a cover, or the like where the printing apparatus needs an artificial intervention, the updating process cannot be normally executed due to the abnormal state.

### SUMMARY OF THE INVENTION

In consideration of the above problems, it is an object of the invention to provide a printing apparatus arranged at a remote place where the updater cannot immediately confirm, in which an evil associated with updating of firmware can be prevented.

The present invention provided a printing apparatus which obtains, through a network, updating data for an updating process to update a control program for executing a printing process on the basis of print data, comprising a confirming unit which confirms its own operating state when the updating data is obtained; and an updating processing unit which starts the updating process in accordance with a confirmation result of the confirming unit.

Moreover, in printing apparatus, the confirming unit may have a non-processed data confirming unit which confirms the presence or absence of the non-processed print data for the printing process.

Moreover, in the printing apparatus, the confirming unit may have an operation confirming unit which confirms its own operation abnormality.

Moreover, in the printing apparatus, the confirming unit may have an adaptation discriminating unit which discriminates whether or not the obtained updating data is adapted to the printing apparatus. Then, the adaptation discriminating unit makes an adaptation discrimination of at least one of an apparatus type, a version number of the updating data, and a data hash value.

Moreover, the printing apparatus may further comprises an E-mail communicating unit which obtains the updating data by E-mail.

Moreover, in the printing apparatus, the updating data may be held in a non-volatile storing unit. Then, when the updating data is stored in the storing unit, storage information showing that the updating data has been stored in the storing unit is formed and held in the non-volatile storing unit. In the case, when the printing apparatus is activated, the confirming unit confirms the presence or absence of the storage information, and when the presence of the storage information is confirmed, the confirming unit starts the updating process on the basis of the updating data held in the storing unit.

Further, the present invention provided an updating method of a control program which obtains, through a network, updating data for an updating process to update a control program for executing a printing process on the basis of print data, comprising the steps of: obtaining the updating data; confirming its own operating state; and starting the updating process in accordance with a confirmation result.

Moreover, in the updating method, in the confirmation of the operating state, the presence or absence of the non-processed print data for the printing process may be confirmed.

Moreover, in the updating method, in the confirmation of the operating state, its own operation abnormality may be confirmed.

Moreover, in the updating method, in the confirmation of the operating state, whether or not the obtained updating data is adapted to the printing apparatus may be discriminated. Then, in the adaptation discrimination, adaptation discrimination of at least one of an apparatus type, a version number of the updating data, and a data hash value is made.

Moreover, in the updating method, the updating data may be obtained by E-mail.

Moreover, in the updating method, the updating data may be held in a non-volatile storing unit. Then, when the updating data is stored in the storing unit, storage information showing that the updating data has been stored in the storing unit is formed and held in the non-volatile storing unit. In the case, when the printing apparatus is activated, the presence or absence of the storage information is confirmed, and when the presence of the storage information is confirmed, the updating process is started on the basis of the updating data held in the storing unit.

According to the printing apparatus of the invention, its own operating state is checked and after it was confirmed that there is no problem in the updating process, the updating process of the firmware is executed. That is, even if the reactivation associated with the updating process occurs, such an evil that the non-processed print data is erased and the printing process cannot be executed or the like can be prevented.

Other features and advantages of the present invention will be apparent from the following description taken in conjunction with the accompanying drawings, in which like reference characters designate the same or similar parts throughout the figures thereof.

### BRIEF DESCRIPTION OF THE DRAWINGS

FIG. 1 is a connection diagram;

FIG. 2 is a block diagram of a printer in the embodiment 1;

FIG. 3 is a functional block diagram of the printer in the embodiment 1;

FIG. 4 is a flowchart showing a concept of the operation of the printer in the embodiment 1;

FIG. 5 is a flowchart showing the operation of a receiving and analyzing process in the embodiment 1;

FIG. 6 is a flowchart showing an adaptation discriminating process;

FIG. 7 is a flowchart showing the operation for discriminating whether or not data is being received;

FIG. 8 is a flowchart showing the operation for discriminating whether or not a printing process is being executed and discriminating an abnormal state;

FIG. 9 is a diagram showing a writing sequence in the normal state;

FIG. 10 is a sequence diagram in the hash error state;

FIG. 11 is a sequence diagram in the writing error state;

FIG. 12 is a flowchart showing a notifying process of an updating result of firmware;

FIG. 13 is a diagram showing a format of an attached file;

FIG. 14 is a block diagram of a printer in the embodiment 2;

FIG. 15 is a functional block diagram of the printer in the embodiment 2;

FIG. 16 is a flowchart showing the operation of the printer in the embodiment 2; and

FIG. 17 is a flowchart showing the operation of a receiving and analyzing process in the embodiment 2.

### DETAILED DESCRIPTION OF THE PREFERRED EMBODIMENTS

An embodiment of the invention will be described in detail hereinbelow with reference to the drawings. In the following explanation, the same or similar component elements in the drawings which are used in the embodiments are designated by the same reference numerals and their overlapped explanation is omitted as much as possible. The embodiments will be described with respect to an example in which a printer is used as a printing apparatus.

### Embodiment 1

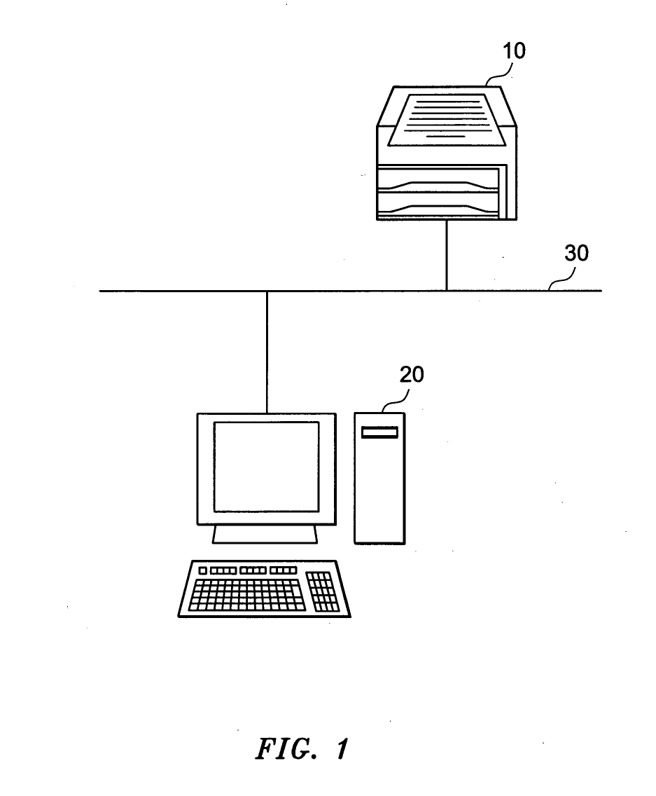

As shown in FIG. 1, a printer 10 of the invention is connected to a terminal 20 of the updater of firmware through a network 30 such as Internet or the like and is network-constructed so that E-mail transmitted from the terminal 20 to the printer 10 can be received by the printing apparatus 10.

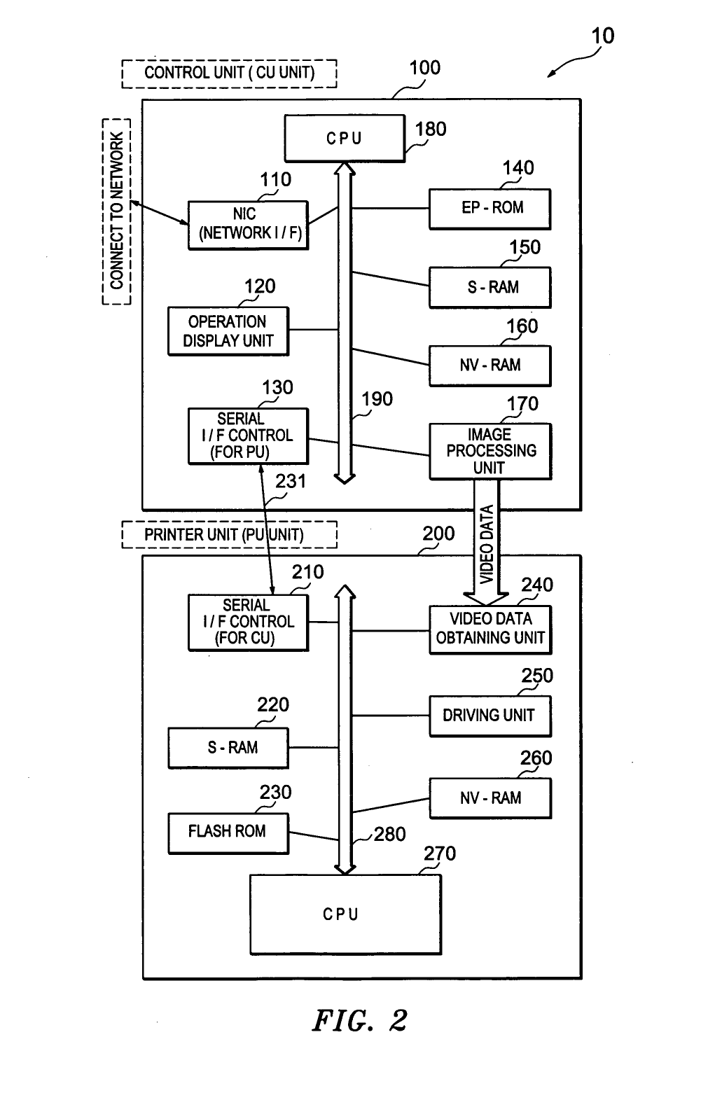

As shown in FIG. 2, the printer 10 comprises: a control unit (hereinafter, also abbreviated to a “CU unit”) 100 for obtaining data through the network and executing a process on the basis of the obtained data; and a printer unit (hereinafter, also abbreviated to a “PU unit”) 200 for executing a printing process on the basis of the data from the control unit 100. The CU unit 100 serially transmits bit map data converted from print data called “video data” for allowing the PU unit 200 to execute the printing process.

The CU unit 100 comprises: a network interface (I/F) 110 called an NIC (Network Interface Card) for network-connecting; an operation display unit 120; a serial interface control unit 130 for serially communicating with the PU unit 200; an EP-ROM (erasable and programmable read only memory) 140 in which a program has been stored; an S-RAM 150 serving as a storing unit; an NV-RAM 160 serving as a non-volatile memory; an image processing unit 170 for raster-developing every print page; a CPU 180 for making control in the CU unit on the basis of the program; and a bus 190 in the CU unit.

The network interface 110 makes control for receiving the print data or E-mail from the terminal 20 through the network.

Updating data for updating the program of the printer 10 as necessary has been attached to the E-mail. The program of the printer 10 is updated on the basis of the updating data.

The operation display unit 120 receives an input based on a display menu and displays an operating situation of the printer.

The serial interface control unit 130 makes communication control for serially communicating with the PU unit 200.

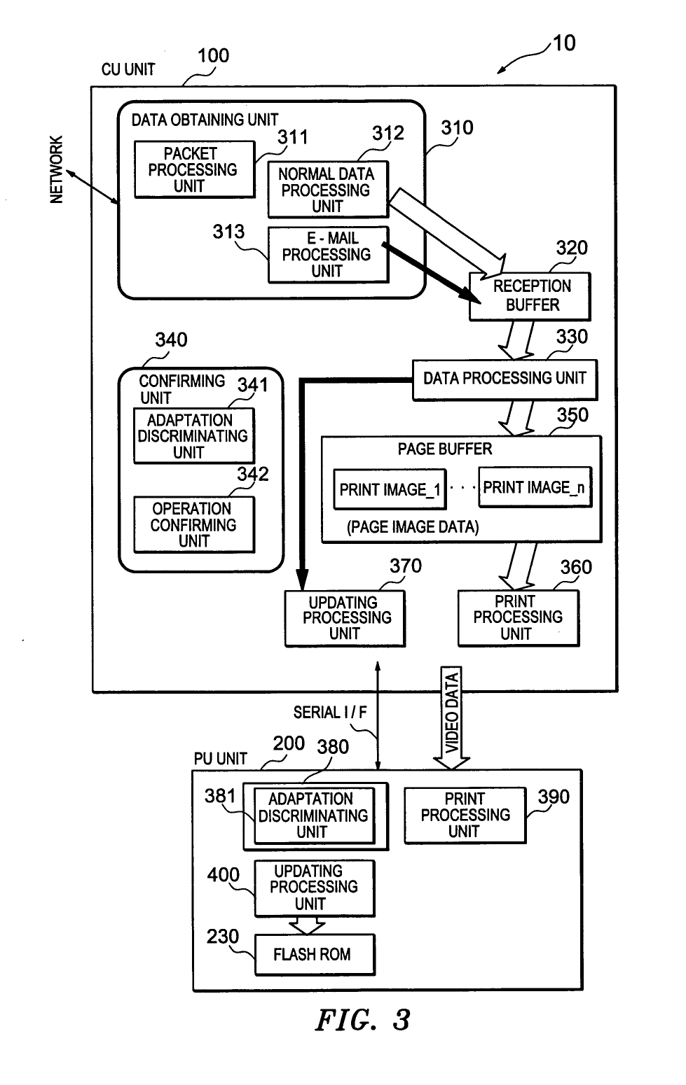

The program for the CPU 180 has been held in the EP-ROM 140. The CPU 180 sequentially reads out the program from the EP-ROM 140 and controls various functions in accordance with the program. As shown in FIG. 3, the functions will be described in detail hereinafter as functional blocks such as data obtaining unit, confirming unit, data processing unit, communication control processing unit, and the like.

The S-RAM 150 is used as: a reception buffer for receiving the data; a work area in processes of the CPU 180 and the image processing unit 170; or a page buffer, which will be explained hereinafter, for holding a processing result.

The reception buffer has been structured. The received data is temporarily stored in a first buffer and, thereafter, the data held in the first buffer is stored in a second reception buffer. The data held in the second reception buffer is sequentially read out and processed in a data processing unit, which will be explained hereinafter.

The NV-RAM 160 is a non-volatile storing unit called a flash memory. Even if a power source of the printer 10 is turned off, the data held in the NV-RAM 160 is not erased but held. The NV-RAM 160 holds contents (menu setting contents) which have been set by the operation display unit 120.

The image processing unit 170 executes a raster process on the basis of the print data expressed by a command of a drawing system received by the network interface 110. The image processing unit 170 forms page image data every page by the raster process and holds the page image data into the page buffer assumed as an area in the NV-RAM 160.

The page image data held in the page buffer is read out every dot line by a reading instruction from the PU unit 200. The read-out data is sent as video data to the PU unit 200 by a communicating function (not shown).

The PU unit 200 comprises: a serial interface control unit 210 for serially communicating with the CU unit 100; an S-RAM 220 serving as a storing unit; a flash ROM 230 for storing the program which is executed in the PU unit 200; a video data obtaining unit 240 for obtaining the video data from the CU unit 100; a driving unit 250 for controlling the driving of various mechanisms to form an image on the basis of the obtained video data; an NV-RAM 260 for holding setting information; a CPU 270 for reading out a program held in the flash ROM 230 and making control in the PU unit 200 on the basis of the program; and a bus 280 in the PU unit.

The S-RAM 220 in the PU unit 200 is used as a work area in processes of the CPU 270 or a memory area for temporarily holding the updating data from the CU unit 100.

The flash ROM 230 holds the program in the PU unit 200 as firmware and rewritably holds it. In the embodiment, the program held in the flash ROM 230 is updated on the basis of the updating data.

The video data obtaining unit 240 makes control for obtaining the video data from the CU unit 100.

The driving unit 250 makes drive control of each mechanism for forming the image on the basis of the video data.

The NV-RAM 260 holds the setting information necessary for the drive control of each mechanism in the driving unit 250. As setting information, for example, information regarding a printing position, information regarding print concentration, and the like can be mentioned.

The CPU 270 controls various functions in accordance with the program held in the flash ROM 230. As shown in FIG. 3, the functions will be described in detail hereinafter as functional blocks such as confirming unit, data updating unit, and the like.

The functions which are controlled by the CPUs 180 and 270 on the basis of programs will now be described with reference to a block diagram of FIG. 3.

The printer 10 comprises: a data obtaining unit (network communicating unit) 310 for making control to obtain the data through the network; a reception buffer 320 for holding the obtained data; a data processing unit 330 for executing an image process if the obtained data is the print data or outputting the obtained data to an updating processing unit, which will be explained hereinafter, if it is the updating data in order to execute a process according to the type of obtained data; a confirming unit 340 for confirming its own operating state, adaptation of the updating data, and its contents; a page buffer 350 for holding the image-processed page data; a print processing unit 360 for obtaining the video data from the page buffer and forming the image; and an updating processing unit 370 for updating the program on the basis of the updating data.

In FIG. 3, the confirming unit 340, the print processing unit 360, and the updating processing unit 370 are provided for the CU unit 100 and a confirming unit 380, a print processing unit 390, and an updating processing unit 400 are provided for the PU unit 200, respectively. This means that the confirming units 340 and 380, the print processing units 360 and 390, and the updating processing units 370 and 400 function on the basis of the program in the CU unit 100 and the program in the PU unit 200, respectively.

The data obtaining unit 310 has a packet processing unit 311, a normal data processing unit 312 of the print data or the like, and an E-mail processing unit 313.

In the packet processing unit 311, a packet which is obtained by the network interface 110 is temporarily held in a first reception buffer (not shown), the packet held in the first reception buffer is read out and analyzed, and either the normal data processing unit 312 or the E-mail processing unit 313 to which the packet should be sent is discriminated.

To process the packet sent from the packet processing unit 311 as print data or control data, the normal data processing unit 312 holds the data into the reception buffer 320 as a second reception buffer.

The E-mail processing unit 313 obtains the updating data attached to the packet sent from the packet processing unit 311 and holds it into the reception buffer 320 serving as a second reception buffer.

In the reception buffer 320, the data from the normal data processing unit 312 and the data from the E-mail processing unit 313 are held in different areas.

The confirming unit 340 has an adaptation discriminating unit 341 and an operation confirming unit 342. The adaptation discriminating unit 341 makes an adaptation discrimination of the updating data and a hash check. The operation confirming unit 342 confirms whether or not the data receiving process is being executed, confirms whether or not the printing process is being executed, and further confirms its own (printer) abnormal state. It is also possible to construct the apparatus in such a manner that the confirming unit 340 confirms each state when a confirming instruction is issued or the confirming unit 340 monitors the latest state, holds it, and notifies the latest state on the basis of the instruction.

The data processing unit 330 reads out the data from the reception buffer 320. When the read-out data is the updating data, the data processing unit 330 outputs it to the updating processing unit 370 and, when it is the print data, the process in the image processing unit 170 is executed. That is, the data processing unit 330 executes the raster process on the basis of the print data, forms the page image data, and holds the formed page image data into the page buffer.

The print processing unit 360 reads out the page image data held in the page buffer 350 every dot line and outputs the read-out data of one dot line as video data to the PU unit 200 from the CU unit 100. In the PU unit 200, the print processing unit 390 which received the video data forms an image of one page on the basis of the video data so as to form the image onto a print medium every dot line. At this time, the print processing unit 390 controls the driving unit 250 and makes paper feed control, control of an image forming drum (not shown) and the like, and control of an ink injection nozzle and the like.

The updating processing unit 370 performs transmission and reception of the updating data between the CU unit 100 and the PU unit 200 through a serial I/F. First, a hash check of the updating data obtained by the CU unit 100 is performed by the adaptation discriminating unit 341 in the confirming unit 340. After that, if there is no problem in the hash check, the operation confirming unit 342 discriminates the state of the apparatus. If there is no problem in the apparatus state, the updating processing unit 370 updates the program held in the flash ROM 230 in the PU unit 200 on the basis of the updating data.

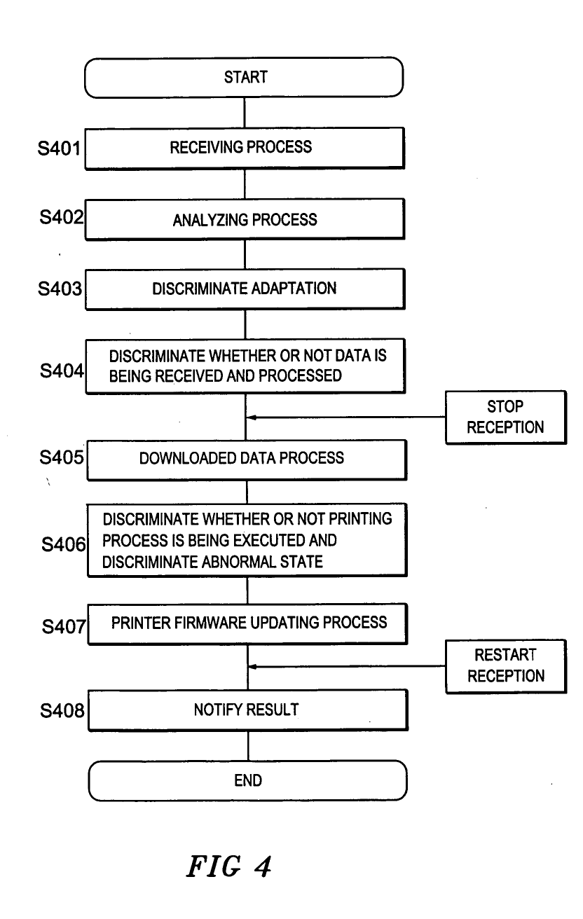

An operation concept of the printer 10 of the invention will now be described with reference to a flowchart of FIG. 4 and, thereafter, its detailed operation will be explained.

The updating of the program will be mainly explained in the following operation description.

A receiving process of the packet is executed in the data obtaining unit 310 (step S401) and an analyzing process of the received packet (data) is executed (step S402).

If it is determined in the analyzing process that the data is the updating data, adaptation of the updating data is discriminated in the adaptation discriminating unit 341 (step S403).

If it is determined that the data is the adapted updating data, the operation confirming unit 342 discriminates whether or not the data is being received and processed (step S404).

If the data is not being received, the updating data is transferred from the first reception buffer to the second reception buffer (step S405). After that, the operation confirming unit 342 discriminates whether or not the printing process is being executed on the basis of a holding situation of the page buffer 350 and discriminates an abnormal state such as jam (paper jam), opening of the cover, or the like (step S406). The operation confirming unit 342 obtains information about the occurrence of the jam and the opening of the cover by inquiring of the PU unit 200 about them.

If the printing process is not being executed and the apparatus is not in the abnormal state, in order to update the firmware (program) on the basis of the updating data, the updating processing unit 370 sends the updating data to the updating processing unit 400 and updates it (step S407). After that, the user is notified of an updating result (step S408).

The operation in each processing step will now be described in detail.

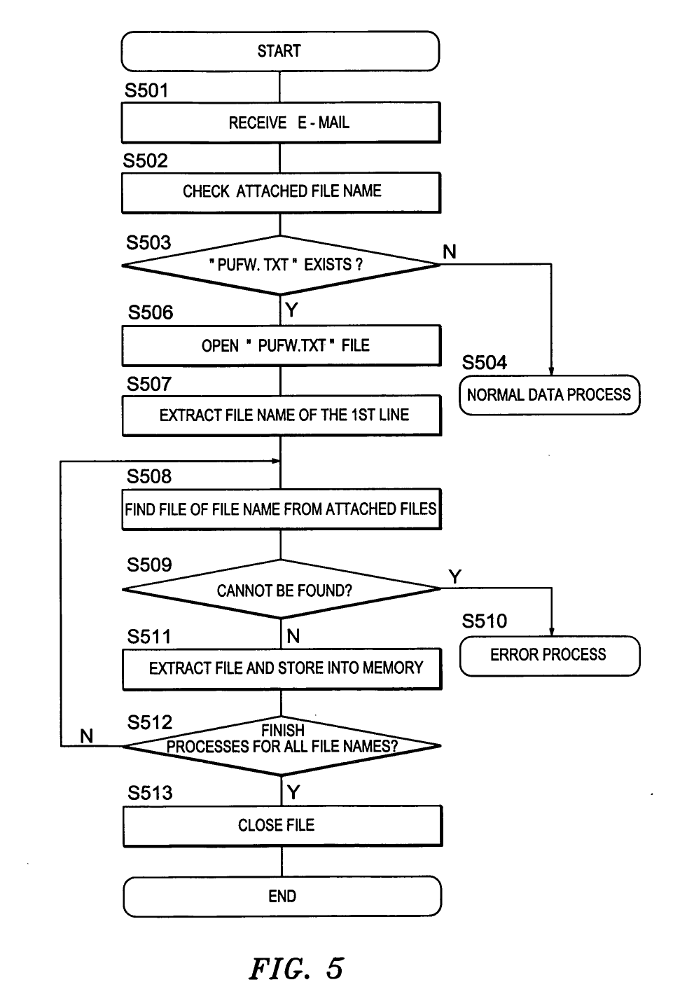

The detailed operations of the receiving process and the analyzing process are shown in a flowchart of FIG. 5. When the packet (data) is received by the data obtaining unit 310 (step S501), the data is held in the first reception buffer. The packet processing unit 311 discriminates whether or not the file has been attached to E-mail shown by the received packet and checks a name of the attached file if the file has been attached (step S502).

If it is determined in this discrimination that the file name is not, for example, “pufw. txt” indicative of the updating data (step S503), the data held in the first reception buffer is sent to the normal data processing unit 312 and the normal data process is executed (step S504). The “pufw. txt” file and the updating data designated by “pufw. txt” have been attached to the E-mail including the updating data.

If the updating data has been attached in step S503 mentioned above, the adaptation discriminating unit 341 opens the received file so as to analyze the contents of the attached data (step S506).

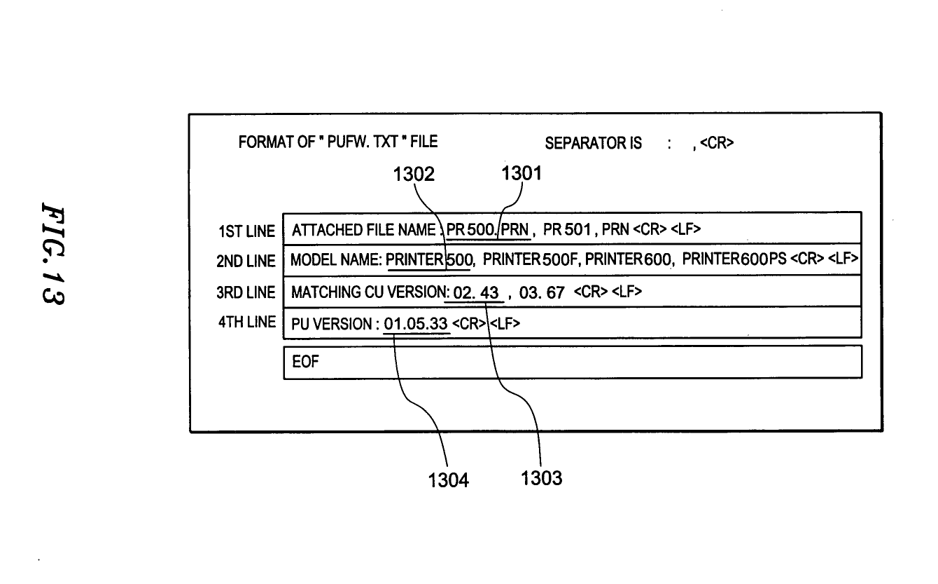

When the file is opened, as shown in FIG. 13, for example, the names of the updating data files attached to the E-mail such as “PR500.PRN” “PR501.PRN” are shown in the first line. For example, model names corresponding to the updating data such as “Printer500”, “Printer500F”, “Printer600”, and “Printer600PS” are shown in the second line. For example, versions (in this case, versions in a range of V02.43 to V03.67 are valid) of the program in the CU unit 100 corresponding to the updating data such as “02.43” and “03.67” are shown in the third line. For example, a version in the PU unit 200 corresponding to the updating data such as “01.05.33” is shown in the fourth line. In FIG. 13, the adaptation in the printer 10 is shown by underlines.

The adaptation discriminating unit 341 confirms the contents shown in the first line, obtains the “file name”, and holds the obtained “file name” into the S-RAM 150 (step S507). As shown in FIG. 13, there is a case where a plurality of “file names” are shown in the first line. All of the “file names” are held in the S-RAM 150.

The adaptation discriminating unit 341 confirms whether or not the file of the “file name” which was temporarily held in the S-RAM 150 has been attached (step S508). If the file of the relevant file name is not attached (step S509), an error process is executed (step S510).

If the file of the “file name” which was temporarily held has been attached in step S508, this file is held in the second reception buffer (step S511). The above processes are executed with respect to all of the “file names” which have temporarily been held (step S512).

After that, the file opened in step S506 is closed (step S513).

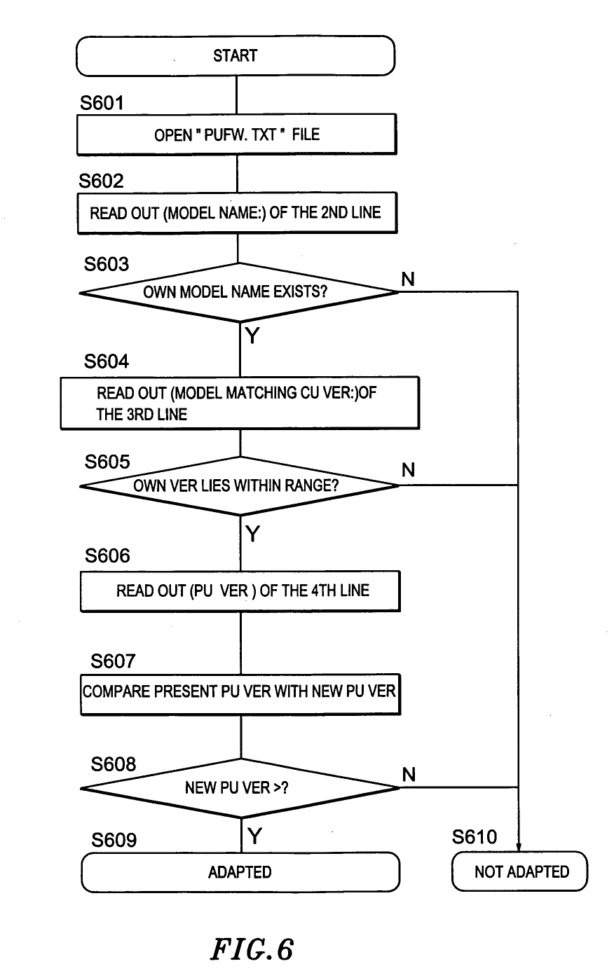

The operation of the adaptation discrimination (step S403) of the updating data in FIG. 4 will now be described with reference to FIG. 6. This process is executed between steps S509 and S511 in the flowchart of FIG. 5.

The adaptation discriminating unit 341 makes the adaptation discrimination. The operation of the adaptation discrimination of the updating data in the adaptation discriminating unit 341 will now be described with reference to a flowchart of FIG. 6.

The adaptation discriminating unit 341 opens the file whose file name is “pufw. txt” (step S601).

The adaptation discriminating unit 341 obtains the model names (apparatus type names) shown in the second line of the file whose file name is “pufw. txt” (step S602) and discriminates whether or not the apparatus type of the printer is shown in the apparatus type names (step S603). When the model name of the printer is not shown in the second line of “pufw. txt”, the updating data is decided not to be adapted and the updating process based on the updating data is not executed (step S610).

When the model name indicates the apparatus type of the printer in step S603, the adaptation discriminating unit 341 obtains the version number of the program of the CU unit shown in the third line of the file whose file name is “pufw. txt” (step S604) and discriminates whether or not the obtained version number of the program is within the version number of the program of the CU unit 100 of the printer (step S605). If the obtained version number of the program of the CU unit is not within the version number of the program of the CU unit 100 of the printer, the updating process based on the updating data is not executed (step S610).

If the obtained version number of the program of the CU unit is within the version number of the program of the CU unit 100 of the printer in step S605, the adaptation discriminating unit 341 obtains the version number of the program of the PU unit shown in the fourth line of the file whose file name is “pufw. txt” (step S606) and compares the obtained version number with the version number of the program of the PU unit 200 of the printer (step S607).

If the version number of the program of the PU unit shown in the fourth line is larger than the version number of the program of the PU unit 200 of the printer, that is, when the program is new (step S608), it is determined that the updating data is adapted (step S609). If it is equal to or smaller than the version number of the program of the PU unit 200, that is, when the program is old, it is determined that the updating data is not adapted (step S610).

Information showing the version number of the program of the CU unit 100 of the printer has been held in the EP-ROM 140 or the NV-RAM 160. Information showing the version number of the program of the PU unit 200 has been held in the S-RAM 220 or the NV-RAM 260. The adaptation discriminating unit 341 reads out the information showing the version number from those storing units as necessary and makes the adaptation discrimination.

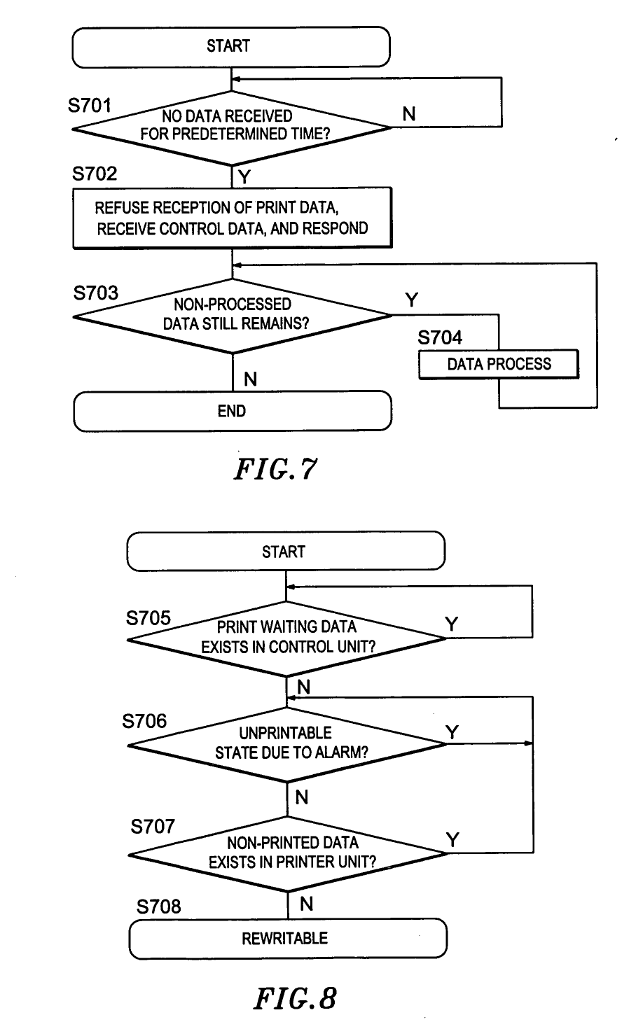

The operation for discriminating whether or not the data is being received (step S404) in FIG. 4 will now be described with reference to FIG. 7.

The operation confirming unit 342 makes the discrimination about whether or not the data is being received. The operation for the data reception discriminating process in the operation confirming unit 342 will be described with reference to a flowchart of FIG. 7.

The operation confirming unit 342 discriminates whether or not the data has been received within a predetermined time (step S701). If the data has been received within the predetermined time in this discrimination, there is a risk of receiving some continuous data on a packet unit basis. If the data is not received within the predetermined time in step S701, the operation confirming unit 342 refuses the reception of the print data. Control data is continuously received and a process corresponding to the control data is executed (step S702). After that the presence or absence of the non-processed data is confirmed (step S703) and the non-processed data is processed (step S704).

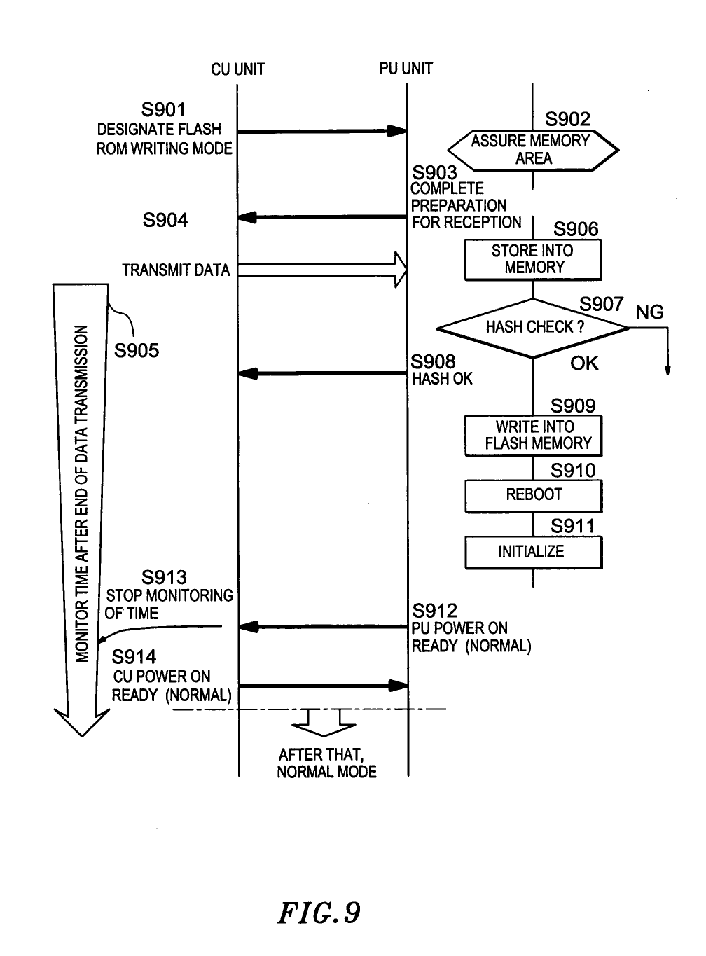

In the downloaded data process (step S405) in FIG. 4, after completion of the processes up to step S404, the updating data held in the first reception buffer is downloaded into the second reception buffer and the subsequent discrimination about whether the printing process is being executed and the apparatus is in the abnormal state in the PU unit 200 is made. As shown in FIG. 8, in this discriminating process, the operation confirming unit 342 confirms the presence or absence of the page image data in the page buffer 350 in the CU unit 100 and discriminates whether or not the apparatus is waiting for the printing (step S705). The updating process of the program is set into a standby mode until the print waiting data is processed in the CU unit 100.

After all of the data in the page buffer 350 in the CU unit 100 is processed, the operation confirming unit 342 confirms an abnormal state in its own operation (step S706). The updating process of the program is set into the standby mode until the abnormal state is eliminated. After that, the non-processed data (1-dot line data) in the PU unit 200 is confirmed (step S707). The updating process of the program is set into the standby mode until the data process in the PU unit 200 is finished, that is, until the printing process in the printer 10 is finished (step S708).

The operation of the updating process of the firmware (step S407) in FIG. 4 will now be described.

First, the operation of the updating processing unit 370 when the firmware is normally updated will be described with reference to a sequence diagram in the CU unit 100 and the PU unit 200 shown in FIG. 9.

The CU unit 100 designates the “flash ROM writing mode” to the PU unit 200 (step S901). The PU unit 200 which received the designated mode assures a memory area of a size of data which is downloaded into the S-RAM 220 (step S902) and notifies the CU unit 100 that preparation for downloading has been completed (step S903).

The CU unit 100 which received such a notification transmits the updating data to the PU unit 200 (step S904). At this time, the CU unit 100 activates a time monitoring timer (not shown) (step S905). When the PU unit 200 obtains the updating data from the CU unit 100 through the video data obtaining unit 240, the updating data is held in the S-RAM 220 (step S906). When all of the updating data is completely obtained, a hash check is made (step S907). The PU unit 200 notifies the CU unit 100 of a check result (step S908).

Thus, when the updating data is transmitted and received between the CU unit 100 and the PU unit 200, the data-transformed updating data can be checked.

If there is no problem in the hash check, the PU unit 200 writes the updating data which has temporarily been held in the S-RAM 220 into the flash ROM 230 (step S909). Thereafter, the reboot (reactivation) is instructed (step S910) and the PU unit 200 is initialized (step S911).

Even if the PU unit 200 is initialized and the data held in the memory such as an S-RAM 220 or the like is initialized, since the non-processed print data does not exist, the print data is not erased in association with the initialization.

After the initialization, the PU unit 200 notifies the CU unit 100 of “PU Power ON Ready (Normal)” showing that a power source of the PU unit 200 has been turned on in association with the initialization (step S912).

The CU unit 100 which received the “PU Power ON Ready (Normal)” notification stops the operating time monitoring timer (step S913), thereafter, notifies the PU unit 200 of “CU Power ON Ready (Normal)” (step S914), and subsequently executes the ordinary operation.

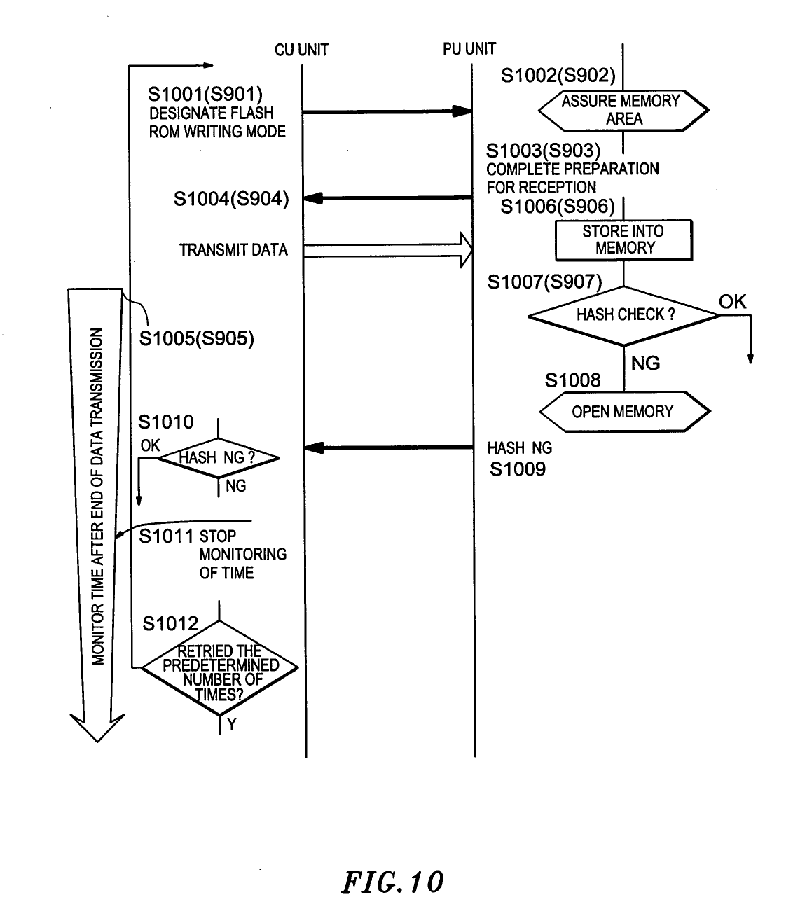

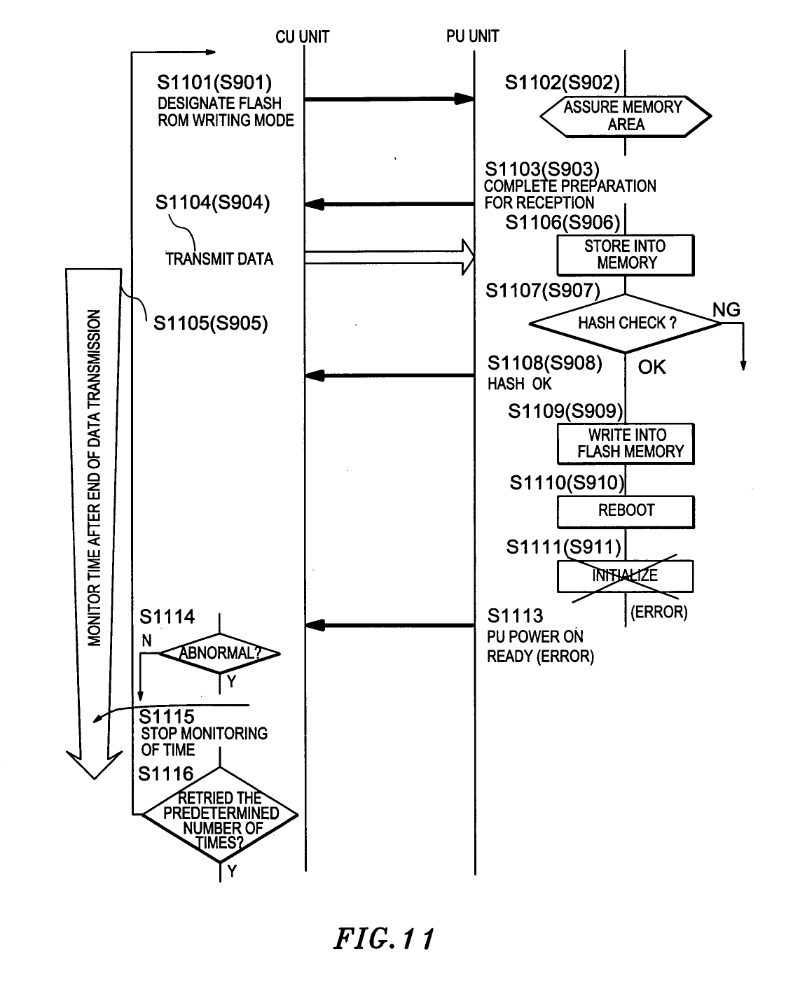

The operation when the hash error has occurred in the hash check (step S907) in FIG. 9 mentioned above will now be described with reference to a sequence diagram of FIG. 10.

When the hash check error occurs (step S1007), the PU unit 200 opens the memory area assured in the S-RAM 220 (step S1008) and notifies the CU unit 100 that the hash check result is NG (step S1009). The CU unit 100 which received the NG notification stops the operating time monitoring timer (step S1011) and retries the updating of the firmware. In this instance, prior to starting the retrying process, the CU unit 100 confirms whether or not the retrying operation has been executed a predetermined number of times (step S1012).

The operation when the initializing process (step S911) after the reboot in FIG. 9 mentioned above is not normally executed will now be described with reference to a sequence diagram of FIG. 11.

When the PU unit 200 detects the abnormality of the initializing process in step S911 (step S1111), it notifies the CU unit 100 of “PU Power ON Ready (Error)” showing the abnormality (step S1113).

The CU unit 100 which received the abnormality notification (step S1114) stops the operating time monitoring timer (step S1115) and retries the updating of the firmware. In this instance, prior to starting the retrying process, the CU unit 100 confirms whether or not the retrying operation has been executed a predetermined number of times (step S1116).

The time monitoring timer is provided to autonomously detects the occurrence of some inconveniences in the case where the updating process of the firmware is not finished within a predetermined time in the updating process of the firmware mentioned above.

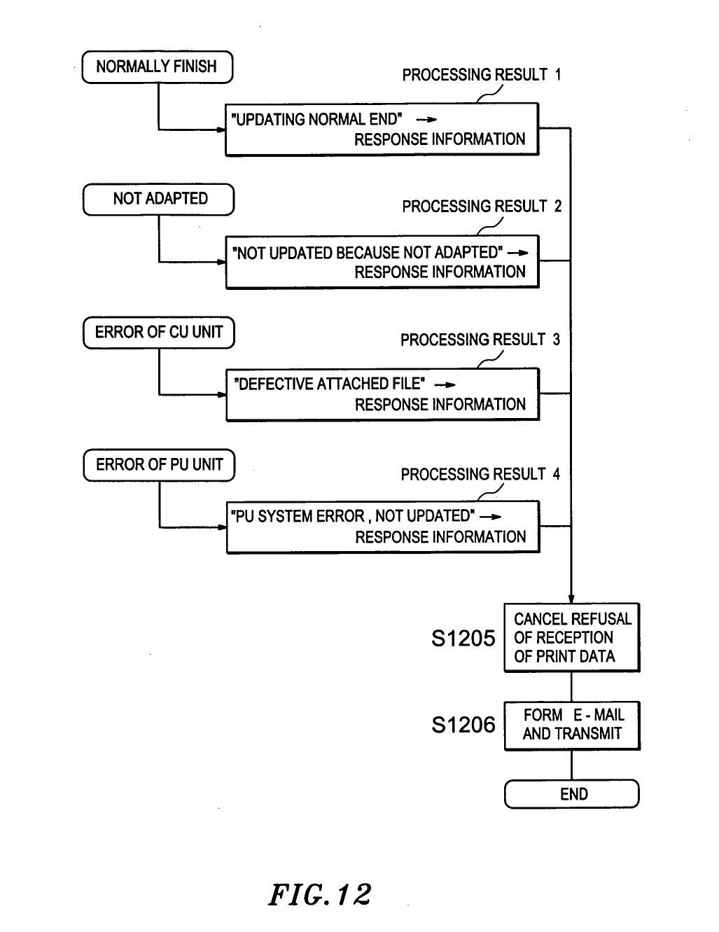

After the updating process of the firmware is executed, a result notifying process of the updating of the firmware in FIG. 4 is executed. In the result notifying process of the updating of the firmware, the following results are notified as shown in FIG. 12: the updating of the firmware has normally been finished (processing result 1); since the updating is not adapted, the process is finished without updating the firmware (processing result 2); the updating data is not correctly attached to the E-mail and the process is finished (processing result 3); the abnormal state is continued for a long time, the hash error occurs, the data cannot be normally written into the flash ROM 230, or an inconvenience exists in the updating data, so that the reactivation cannot be normally executed (processing result 4); and the like. The updating processing unit 370 which obtained at least one of them as a processing result cancels the stopped reception of the print data (step S1205). After that, the updating processing unit 370 forms E-mail indicative of the processing result and transmits it to the terminal 20 (step S1206).

The updating administrator who received the E-mail showing the processing results 2 and 3 mentioned above confirms the updating data (transmission file) transmitted to the printer 10. When the updating result of the firmware indicates the processing results 4 and 5, it is necessary to perform maintenance of the printer 10.

As mentioned above, according to the printer 10 of the invention, since its own operating state is confirmed prior to updating the firmware, the extinction of the non-processed data due to the reboot associated with the updating process of the firmware is not caused. The evil associated with the updating process of the firmware can be prevented.

In the above embodiment, after the updating data is transmitted and received between the CU unit 100 and the PU unit 200, the hash check of the updating data is made. However, the hash check can be also made in the adaptation discriminating unit 341 when the updating data is received from the terminal 20.

### Embodiment 2

A printer which holds the received updating data by a device storage serving as a non-volatile storing unit will now be described.

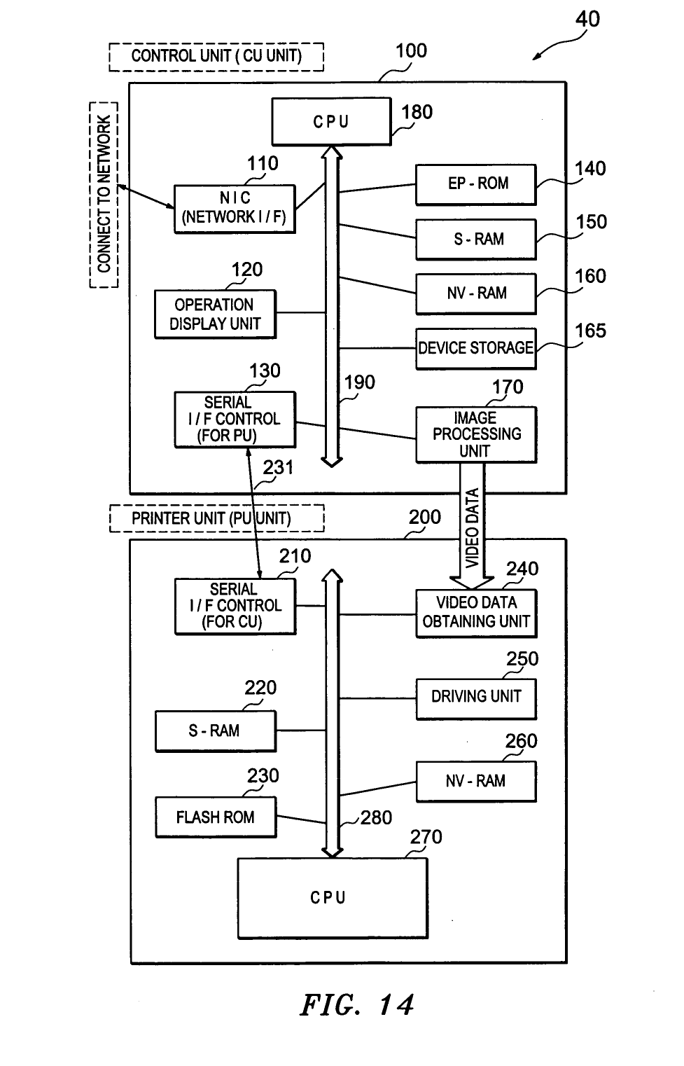

As shown in FIG. 14, a printer 40 in the embodiment 2 is constructed by adding a device storage 165 (for example, a hard disk memory or the like) serving as a non-volatile storing unit to the construction of the embodiment 1 mentioned above. The device storage 165 is provided for the CU unit 100.

Even if a power source of the printer 40 is turned off after the updating data is held in the device storage 165, the updating data held in the device storage 165 is not extinguished but held.

When the updating data is held in the device storage 165, a download flag is set to ON in order to form storage information showing that the updating data has been downloaded into the device storage 165. The download flag is held in the NV-RAM 160 and is not erased even if the power source of the printer 40 is turned off.

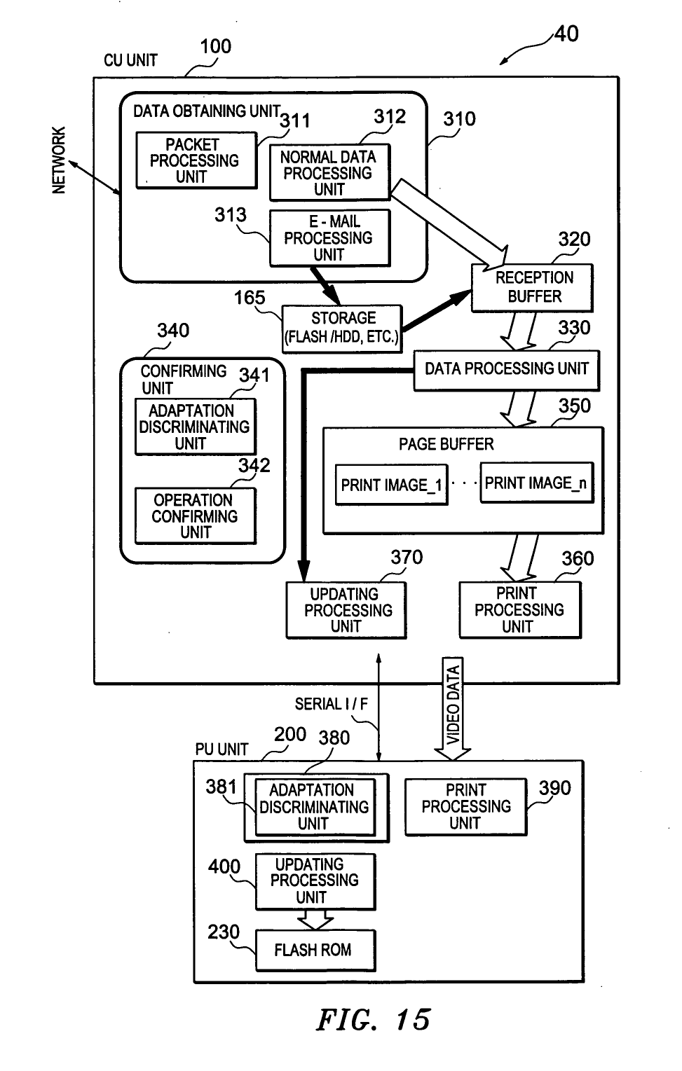

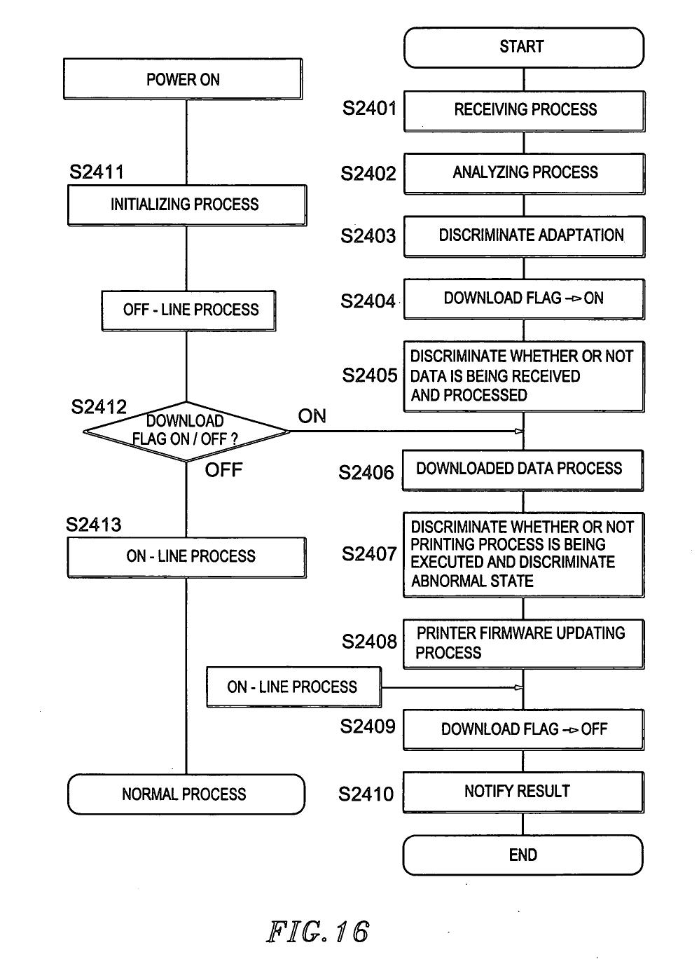

Subsequently, a relation between the download flag and the device storage 165 in the printer 40 of the embodiment 2 will be described with reference to a block diagram of FIG. 15. As shown in FIG. 15, according to the printer 40 of the embodiment 2, the device storage 165 to hold the updating data from the E-mail processing unit 313 is added to the functional construction of the embodiment 1 mentioned above.

In the E-mail processing unit 313 of the embodiment 2, the adaptation discriminating unit 341 discriminates whether or not it is permitted to download the updating data attached to the packet sent from the packet processing unit 311 into the device storage 165. The updating data in which it is determined by the adaptation discriminating unit 341 that the updating data can be downloaded is outputted from the packet processing unit 311 to the device storage 165. When the device storage 165 holds the updating data from the E-mail processing unit 313, it sets the download flag to ON and, further, holds the updating data into the reception buffer 320.

When the updating data held in the reception buffer 320 is sent to the updating processing unit 370 through the data processing unit 330, the updating processing unit 370 allows the operation confirming unit 342 to discriminate whether or not the data is being received, the printing process is being executed, and the apparatus is in the abnormal state. If the apparatus is not in those states, the updating processing unit 370 outputs the updating data to the PU unit 200. The updating processing unit 400 of the PU unit 200 updates the program held in the flash ROM 230 by the obtained updating data. After the updating, when the updating processing unit 370 receives an updating completion notification, it sets the download flag to OFF.

After the updating data was held in the device storage 165, when the power source of the printer 40 is turned off without completing the updating of the firmware and, subsequently, the power source is again turned on, the updating processing unit 370 checks the download flag prior to on-line control (network communication connection control). If the flag has been set to ON, the updating processing unit 370 reads out the updating data from the device storage 165 and executes the updating process of the firmware in a manner similar to that mentioned above.

The operation upon updating of the firmware of the printer 40 will now be described with reference to a flowchart of FIG. 16. The operation when the power source is turned on will be also described with reference to the same flowchart.

A receiving process of the packet is executed in the data obtaining unit 310 (step S2401) and an analyzing process of the received packet (data) is executed (step S2402).

If it is determined by the analyzing process that the received packet (data) is the updating data, the adaptation discrimination of the updating data is made by the adaptation discriminating unit 341 (step S2403). If it is decided that the received packet (data) is the adapted updating data, the updating data is held in the device storage 165.

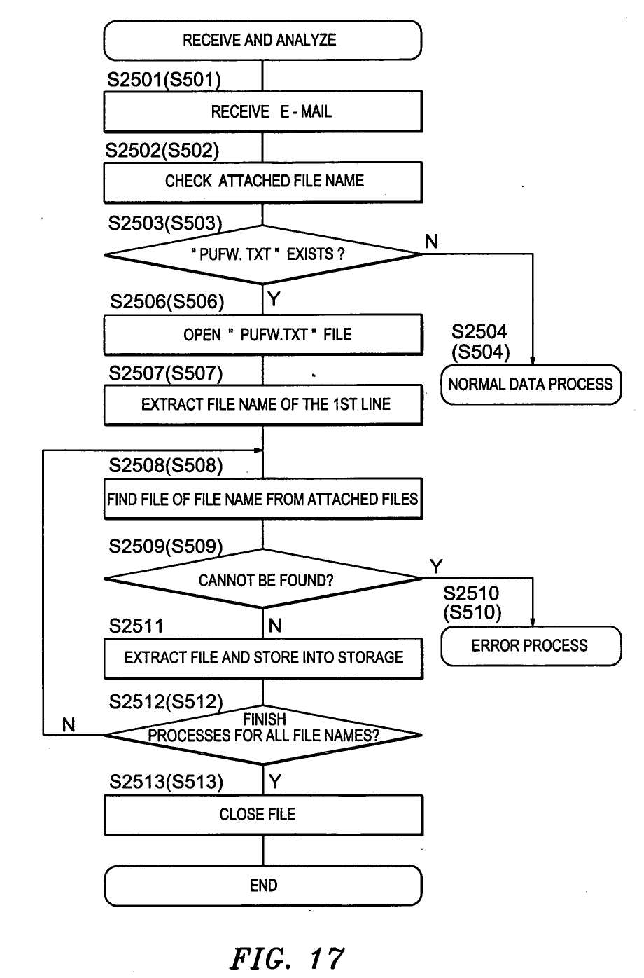

The operation to hold the updating data into the device storage 165 will now be described with reference to a flowchart of FIG. 17. Since the operation in a range from step S2501 to receive the E-mail to step S2510 to analyze the E-mail is similar to that in the embodiment 1 mentioned above, its explanation is omitted here.

In step S2509 in FIG. 17, the adaptation discriminating unit 341 confirms whether or not the file of the “file name” which was temporarily held in the S-RAM 150 has been attached. If the file of the “file name” which was temporarily held has been attached (step S2510), this file is held in the device storage 165 (step S2511). The above processes are executed in all “file names” which were temporarily held (step S2512).

Thus, all of the updating data in which it is determined by the adaptation discriminating unit 341 that the data is adapted is held in the device storage 165.

After that, when the updating data is held in the device storage 165, the download flag is set to ON (step S2404). After that, the operation confirming unit 342 discriminates whether or not the data is being received and processed (step S2405).

When the data is not being received and processed, the updating data is transferred to the reception buffer (step S2406). After that, the operation confirming unit 342 discriminates whether or not the printing process is being executed on the basis of the holding situation of the page buffer 350 and also discriminates the abnormal state (step S2407). If the printing process is not being executed and is not in the abnormal state, the updating processing unit 370 updates the firmware (program) on the basis of the updating data (step S2408). When the updating process of the firmware is finished, the updating processing unit 370 sets the download flag to OFF (step S2409). After that, the terminal 20 is notified of the updating result.

Subsequently, the operation in the case where although the updating data was received, the power source of the printer 40 is turned off without executing the updating process and, thereafter, the power source is again turned on will be described.

First, when the power source is turned on, an initializing process to make the check of the ROM and RAM and the like is executed (step S2411). After that, the download flag held in the NV-RAM 160 is checked. When the flag is ON, the process from step S2406 to transfer the updating data held in the device storage 165 to the reception buffer 320 is executed.

If the download flag is OFF in step S2412 mentioned above, the network line connection control (on-line process) is made (step S2413), thereby preparing for the reception of the print data.

As mentioned above, according to the printer 40 in the embodiment 2, when the updating data is held in the device storage 165, the download flag is set to ON. Thus, even if the power source is turned off during the updating of the firmware, the download flag is confirmed and when it is ON, the updating data held in the device storage 165 is read out and the updating of the firmware can be successively executed.

It is unnecessary that the invention is limited to the printer but the invention can be also applied to an apparatus having a printing function such as facsimile apparatus, multifunction apparatus, or the like which can obtain data through the network.

It should be understood by those skilled in the art that various modifications, combinations, sub-combinations and alterations may occur depending on design requirements and other factors insofar as they are within the scope of the appended claims or the equivalents thereof.

What is claimed is:

1. A printing apparatus which obtains, through a network, updating data for an updating process to update a control program for executing a printing process on the basis of print data, comprising:
a confirming unit which confirms its own operating state when said updating data is obtained; and
an updating processing unit which starts said updating process in accordance with a confirmation result of said confirming unit.

2. The printing apparatus according to claim 1, wherein said confirming unit has a non-processed data confirming unit which confirms the presence or absence of the non-processed print data for said printing process.

3. The printing apparatus according to claim 1, wherein said confirming unit has an operation confirming unit which confirms its own operation abnormality.

4. The printing apparatus according to claim 1, wherein said confirming unit has an adaptation discriminating unit which discriminates whether or not said obtained updating data is adapted to said printing apparatus.

5. The printing apparatus according to claim 4, wherein said adaptation discriminating unit makes an adaptation discrimination of at least one of an apparatus type, a version number of the updating data, and a data hash value.

6. The printing apparatus according to claim 1, further comprising an E-mail communicating unit which obtains said updating data by E-mail.

7. The printing apparatus according to claim 1, wherein said updating data is held in a non-volatile storing unit.

8. The printing apparatus according to claim 7, wherein when said updating data is stored in said storing unit, storage information showing that said updating data has been stored in the storing unit is formed and held in said non-volatile storing unit.

9. The printing apparatus according to claim 8, wherein when said printing apparatus is activated, said confirming unit confirms the presence or absence of said storage information, and when the presence of said storage information is confirmed, said confirming unit starts the updating process on the basis of the updating data held in said storing unit.

10. An updating method of a control program which obtains, through a network, updating data for an updating process to update a control program for executing a printing process on the basis of print data, comprising the steps of:
obtaining said updating data;
confirming its own operating state; and
starting said updating process in accordance with a confirmation result.

11. The updating method according to claim 10, wherein in the confirmation of said operating state, the presence or absence of the non-processed print data for said printing process is confirmed.

12. The updating method according to claim 10, wherein in the confirmation of said operating state, its own operation abnormality is confirmed.

13. The updating method according to claim 10, wherein in the confirmation of said operating state, whether or not said obtained updating data is adapted to said printing apparatus is discriminated.

14. The updating method according to claim 13, wherein in said adaptation discrimination, adaptation discrimination of at least one of an apparatus type, a version number of the updating data, and a data hash value is made.

15. The updating method according to claim 10, wherein said updating data is obtained by E-mail.

16. The updating method according to claim 10, wherein said updating data is held in a non-volatile storing unit.

17. The updating method according to claim 16, wherein when said updating data is stored in said storing unit, storage information showing that said updating data has been stored in the storing unit is formed and held in said non-volatile storing unit.

18. The updating method according to claim 17, wherein when said printing apparatus is activated, the presence or absence of said storage information is confirmed, and when the presence of said storage information is confirmed, the updating process is started on the basis of the updating data held in said storing unit.
